(19) United States
(12) Patent Application Publication
(10) Pub. No.: US 2026/0059246 A1
(43) Pub. Date: Feb. 26, 2026

(54) MAIN BODY OF WATERPROOF HEARING AID

(71) Applicant: Xiamen Retone Hearing Technology Co., Ltd., Xiamen (CN)

(72) Inventors: Yiquan SHI, Xiamen (CN); Chengxiang ZHANG, Xiamen (CN); Zhiqiang SU, Xiamen (CN)

(73) Assignee: Xiamen Retone Hearing Technology Co., Ltd., Xiamen (CN)

(21) Appl. No.: 19/309,633

(22) Filed: Aug. 26, 2025

(30) Foreign Application Priority Data
Aug. 26, 2024 (CN) 2024220742361

(51) Int. Cl. H04R 25/00; H04R 25/02; H05K 5/06

(52) U.S. Cl. CPC H04R 25/65; H04R 25/02; H04R 25/603; H05K 5/069; H04R 2225/61

(57) ABSTRACT

A main body of a waterproof hearing aid includes a body portion, a body mounting housing located outside the body portion, and buttons located on the body mounting housing, where the body portion includes a liner, a waterproof pad located above the liner, a flexible printed circuit (FPC) board, and a circuit board located inside the liner; the body mounting housing is provided with button openings; a contact end located at an inner end of each button extends into the body mounting housing from the button opening; the waterproof pad is located on the FPC board; the FPC board is connected to the circuit board; and the contact end of each button is configured to press down on a touch switch on the FPC board through the waterproof pad, thereby connecting the circuit board.

### CROSS REFERENCE TO THE RELATED APPLICATIONS

This application is based upon and claims priority to Chinese patent application No. 202422074236.1, filed on August 26, 2024, the entire contents of which are incorporated herein by reference.

### TECHNICAL FIELD

The present disclosure relates to the technical field of hearing aid design and manufacture, and in particular to a main body of a waterproof hearing aid.

### BACKGROUND

With the increasing severity of global aging, the number of people with hearing loss is increasing. Hearing aids are undoubtedly one of the most effective ways to compensate for hearing loss. Hearing aids are hearing assistance devices suitable for people with hearing loss or impairment, and can amplify the volume of outside sound and smoothly transmit the sound to the auditory center of the brain. In order to maintain good hearing, users need to wear hearing aids at all times. During the period of wearing of hearing aids, users sweat due to hot weather, exercise, or stay in a humid environment, existing hearing aids with a poor waterproof performance are prone to malfunction due to water or sweat intrusion, which affects the service life of the hearing aids. In the traditional technology, a waterproof membrane is provided inside the main body of the hearing aid, the power module and the circuit module are housed and sealed inside the waterproof membrane, and the housing of the main body of the hearing aid wraps the waterproof membrane. Due to the wrapping method of the waterproof membrane, the waterproof structure increases the size and weight of the main body. In addition, during wearing and use, the button acts on the waterproof membrane, and can easily cause the waterproof membrane to rupture, thereby resulting in waterproof failure.

Chinese patent application CN210781349U discloses a waterproof hearing aid, including a main body. The main body of the hearing aid includes a housing, and the housing is provided with a receiving slot for mounting buttons. The receiving slot is provided therein with a sealing component. The button is in contact with and connected in a sealed manner to the sealing component, thereby achieving sealing of the penetrate-through button and eliminating the waterproof membrane bag provided inside the main body in the existing technology. The device solves the problems of bulky waterproof structure, complex assembly, and high cost faced by existing hearing aids. However, due to the use of the penetrate-through button, it is hard to achieve complete sealing and waterproofing to a certain extent, and there is still a possibility that water infiltrating into the button, which affects the use efficiency and service life of the hearing aid.

### SUMMARY

An objective of the present disclosure is to provide a main body of a waterproof hearing aid. Buttons control the operation of a circuit board through a waterproof pad and a flexible printed circuit (FPC) board, achieving complete sealing and waterproofing to a certain extent, improving the service efficiency of the hearing aid, and prolonging the service life of the hearing aid. To achieve the above objective, the present disclosure adopts the following technical solution.

The present disclosure provides a main body of a waterproof hearing aid, including: a body portion, a body mounting housing located outside the body portion, and buttons located on the body mounting housing, where the body portion includes a liner, a waterproof pad located above the liner, a flexible printed circuit (FPC) board, and a circuit board located inside the liner;

the body mounting housing is provided with button openings; each button includes an outer end serving as a pressing end and an inner end serving as a contact end; and the contact end extends into the body mounting housing from the button opening; and

the waterproof pad is located on a touch switch of the FPC board; the waterproof pad is configured to perform sealed covering below the button opening; the FPC board is connected to the circuit board; and the contact end of each button is configured to press down on the touch switch on the FPC board through the waterproof pad, thereby connecting the circuit board.

Furthermore, the body portion further includes a battery located inside the liner; an end of the FPC board is provided with a downward bending battery charging connection portion; and the FPC board is connected to the battery through the battery charging connection portion.

Furthermore, the circuit board is provided with a chip; the circuit board is further provided with a socket connector attached to the bottom thereof by surface mounted technology (SMT); a side of the FPC board is provided with

a downward bending extension portion; the extension portion is provided with a connection plug; and the FPC board is connected to the socket connector on the circuit board through the connection plug.

Furthermore, the body mounting housing includes an upper housing and a lower housing; the body portion is provided with a circle of waterproof flexible glue at the connection between the upper housing and the lower housing; and the waterproof flexible glue is provided in the upper housing through over-molding.

Furthermore, a middle portion of a pad body of the waterproof pad is provided with an upward boss; and the boss is connected to the contact end of each button.

Furthermore, each button is further provided with mounting buckles at two sides of the contact portion; an upper surface of the waterproof pad is provided with grooves corresponding to the mounting buckles; and the mounting buckles are connected to the grooves.

Preferably, an overall thickness of the pad body is 0.5-1 mm, and a thickness of the boss is 0.2-0.5 mm.

Furthermore, the liner is provided with a corresponding mounting protrusion; the waterproof pad and the FPC board are respectively provided with a waterproof pad mounting hole and an FPC board mounting hole; and the mounting protrusion passes through the waterproof pad mounting hole and the FPC board mounting hole to achieve fixation.

Preferably, the waterproof pad is a soft rubber pad.

With the above technical solution, the present disclosure has the following beneficial effects:

1. In the present disclosure, the buttons do not adopt a penetrate-through mounting method. Instead, the buttons are connected to the circuit board through the waterproof pad and the FPC board, achieving complete sealing and waterproofing to a certain extent, improving the service efficiency of the hearing aid and prolonging the service life of the hearing aid.

2. In the present disclosure, the waterproof pad is a soft rubber pad, which is used in conjunction with the FPC board to ensure the contact effect between the buttons and the circuit board and improve the efficiency of the hearing aid.

3. The present disclosure has a simple structure, reduces the production cost of the waterproof hearing aid, and improves the utilization rate of the waterproof hearing aid.

### BRIEF DESCRIPTION OF THE DRAWINGS

FIG. 1 is a three-dimensional structural diagram of the present disclosure;

FIG. 2 is an exploded view of a body portion according to the present disclosure;

FIG. 3 is a top view of the present disclosure;

FIG. 4 is a sectional view taken along an A-A direction shown in FIG. 3;

FIG. 5 is a structural diagram of connections of buttons, a waterproof pad, and an FPC board according to the present disclosure;

FIG. 6 is an enlarged view of B shown in FIG. 5;

FIG. 7 is a three-dimensional partial sectional view of the present disclosure; and

FIG. 8 is a structural diagram of connection of the FPC board and a circuit board according to the present disclosure.

### REFERENCE NUMERALS:

1. body mounting housing; 11. upper housing; 12. lower housing; 2. button; 21. pressing end; 22. contact end; 23. mounting buckle; 3. body portion; 31. waterproof pad; 311. pad body; 312. boss; 313. groove; 314. waterproof pad mounting hole; 32. FPC board; 321. touch switch; 322. battery charging connection portion; 323. connection plug; 324. FPC board mounting hole; 33. circuit board; 331. socket connector; 34. liner; 341. mounting protrusion; 35. battery; and 36. waterproof flexible glue.

### DETAILED DESCRIPTION OF THE EMBODIMENTS

To make the objectives, technical solutions and the advantages of the present disclosure clearer, the present disclosure is described in further detail below with reference to the drawings and embodiments.

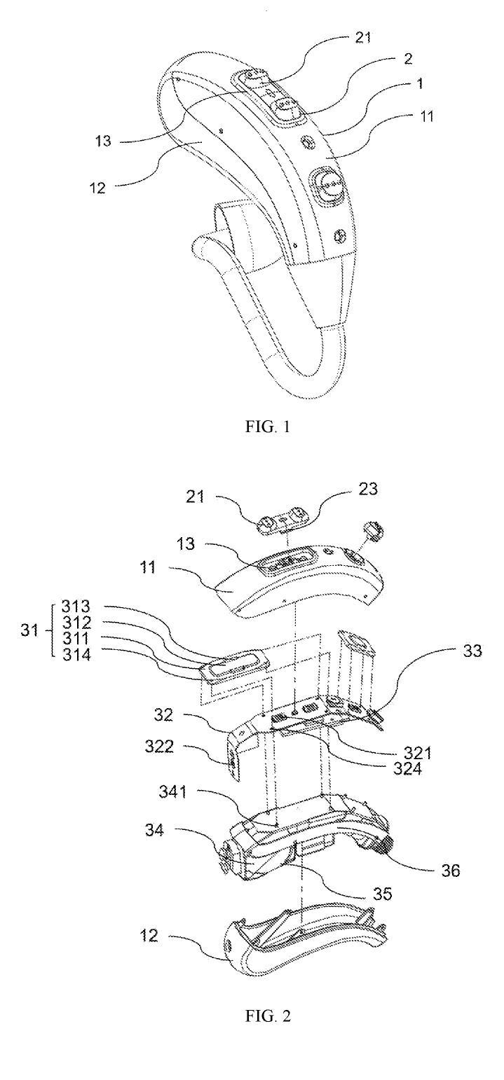

As shown in FIGS. 1 and 2, the present disclosure provides a main body of a waterproof hearing aid, including: body portion 3, body mounting housing 1 located outside the body portion, and buttons 2 located on the body mounting housing 1. The body portion 3 includes liner 34, waterproof pad 31 located above the liner 34, flexible printed circuit (FPC) board 32, and circuit board 33 located inside the liner 34.

The body mounting housing 1 is provided with button openings 13. Each button 2 includes an outer end serving as pressing end 21 and an inner end serving as contact end 22. The contact end 22 extends into the body mounting housing 1 from the button opening 13.

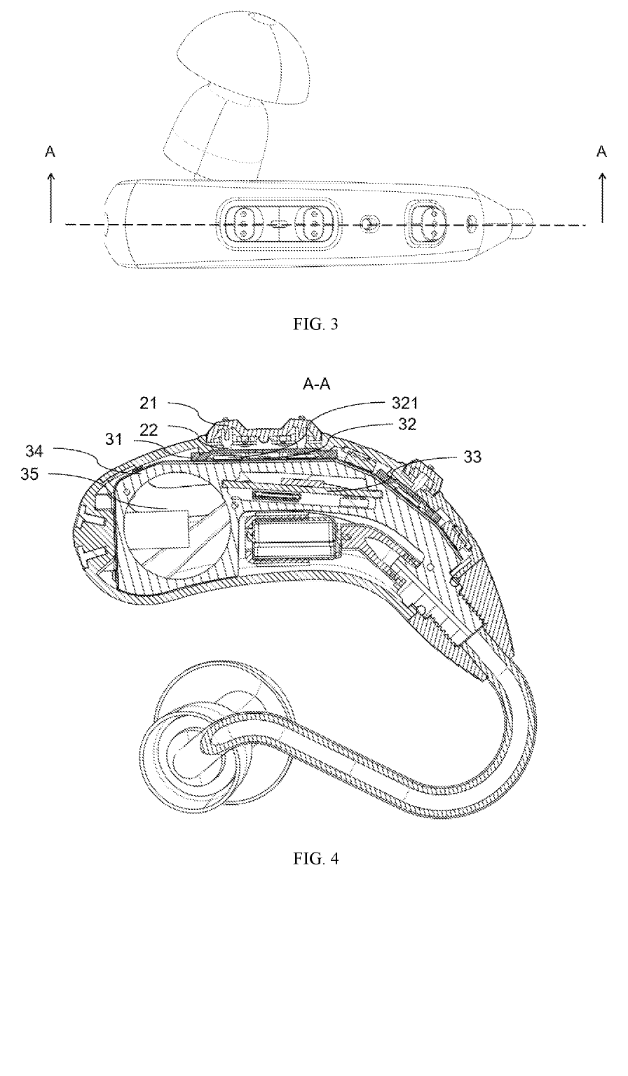

As shown in FIGS. 3 and 4, the waterproof pad 31 is located on touch switch 321 of the FPC board 32. The waterproof pad 31 is configured to perform sealed covering below the button opening 13. The FPC board 32 is connected to the circuit board 33. The contact end 22 of the button 2 is configured to press down on the touch switch 321 on the FPC board 32 through the waterproof pad 31, thereby connecting the circuit board 33.

In this embodiment, the liner 34 is provided with corresponding mounting protrusions 341. The waterproof pad 31 and the FPC board 32 are respectively provided with waterproof pad mounting hole 314 and FPC board mounting hole 324. The mounting protrusions 341 pass through the waterproof pad mounting hole 314 and the FPC board mounting hole 324 to achieve fixation.

As shown in FIGS. 2 and 4, the body portion 3 further includes battery 35 located inside the liner 34. An end of the FPC board 32 is provided with downward bending battery charging connection portion 322. The FPC board 32 is connected to the battery 35 through the battery charging connection portion 322.

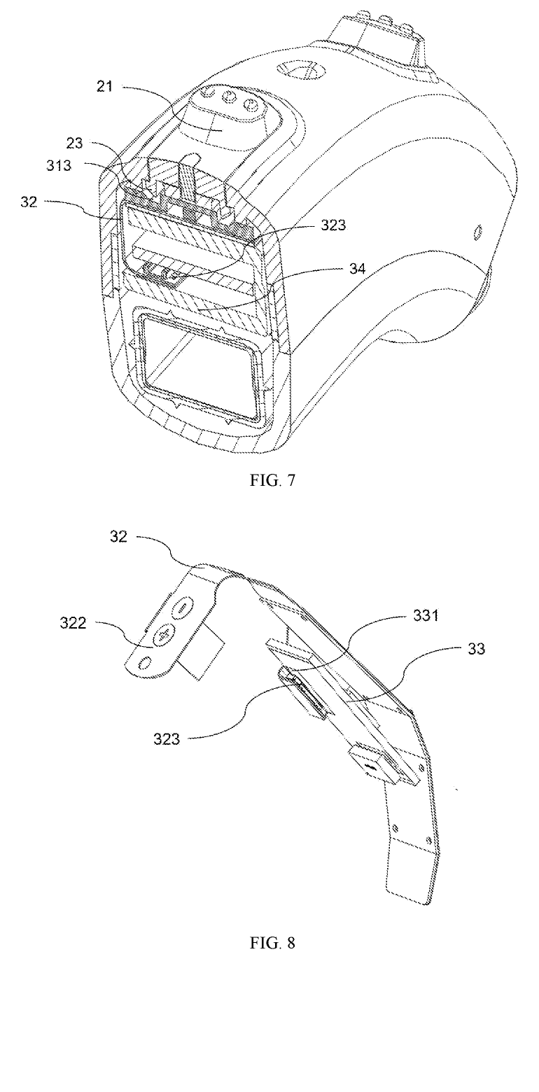

As shown in FIGS. 7 and 8, in this embodiment, the circuit board 33 is provided with a chip. The circuit board 33 is further provided with socket connector 331 attached to the bottom thereof by SMT. A side of the FPC board is provided with a downward bending extension portion. The extension portion is provided with connection plug 323. The FPC board 32 is connected to the socket connector 331 on the circuit board 33 through the connection plug 323.

In addition, as shown in FIGS. 1 and 2, the body mounting housing 1 includes upper housing 11 and lower housing 12. The body portion 3 is provided with a circle of waterproof flexible glue 36 at a connection between the upper housing 11 and the lower housing 12. The waterproof flexible glue 36 is provided in the upper housing 11 through over-molding.

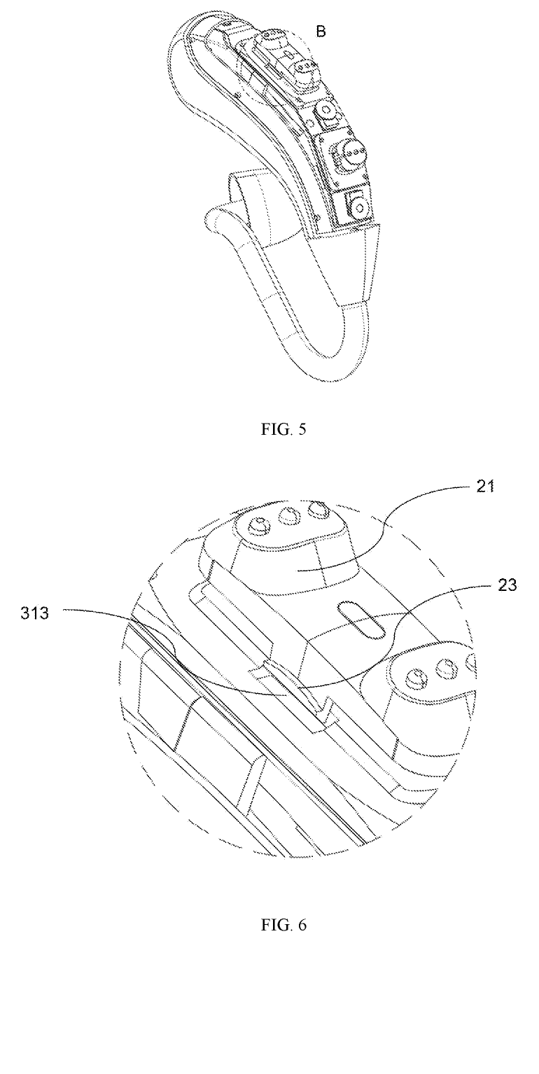

As shown in FIGS. 5, 6, and 7, a middle portion of pad body 311 of the waterproof pad 31 is provided with upward boss 312. The boss 312 is connected to the contact end 22 of the button 2. Each button 2 is further provided with mounting buckles 23 at two sides of the contact portion 22. Two sides of an upper surface of the waterproof pad 31 are provided with grooves 313 corresponding to the mounting buckles 23. The mounting buckle 23 is connected to the groove 313.

In this embodiment, the waterproof pad 31 is a soft rubber pad. An overall thickness of the pad body 311 is 0.5 mm, and a thickness of the boss 312 is 0.2 mm. In other embodiments, the overall thickness of the pad body 311 is 0.5-1 mm, and the thickness of the boss 312 is 0.2-0.5 mm.

The above described are merely specific implementations of the present disclosure. Any modification or replacement easily conceived by those skilled in the art within the technical scope of the present disclosure should fall within the protection scope of the present disclosure.

1. A main body of a waterproof hearing aid, comprising:
a body portion, a body mounting housing located outside the body portion, and at least one button located on the body mounting housing, wherein
the body portion comprises a liner, a waterproof pad located above the liner, a flexible printed circuit (FPC) board, and a circuit board located inside the liner;
the body mounting housing is provided with at least one button opening;
the at least one button comprises an outer end serving as a pressing end and an inner end serving as a contact end; and
the contact end extends into the body mounting housing from the at least one button opening; and
the waterproof pad is located on a touch switch of the FPC board;
the waterproof pad is configured to perform sealed covering below the at least one button opening;
the FPC board is connected to the circuit board; and
the contact end of the at least one button is configured to press the touch switch on the FPC board through the waterproof pad, thereby achieving a connection of the circuit board.

2. The main body of the waterproof hearing aid according to claim 1, wherein the body portion further comprises a battery located inside the liner;
an end of the FPC board is provided with a battery charging connection portion, and the battery charging connection portion bends downward; and
the FPC board is connected to the battery through the battery charging connection portion.

3. The main body of the waterproof hearing aid according to claim 1, wherein the circuit board is provided with a chip;
the circuit board is further provided with a socket connector attached to a bottom of the circuit board by surface mounted technology (SMT);
a side of the FPC board is provided with an extension portion, and the extension portion bends downward;
the extension portion is provided with a connection plug; and
the FPC board is connected to the socket connector on the circuit board through the connection plug.

4. The main body of the waterproof hearing aid according to claim 1, wherein the body mounting housing comprises an upper housing and a lower housing; the body portion is provided with a circle of waterproof flexible glue at a connection between the upper housing and the lower housing; and the waterproof flexible glue is provided in the upper housing through over-molding.

5. The main body of the waterproof hearing aid according to claim 1, wherein a middle portion of a pad body of the waterproof pad is provided with a boss, and the boss protrudes upward; and the boss is connected to the contact end of the at least one button.

6. The main body of the waterproof hearing aid according to claim 5, wherein the at least one button is further provided with mounting buckles at two sides of the contact portion;
an upper surface of the waterproof pad is provided with grooves corresponding to the mounting buckles; and
the mounting buckles are connected to the grooves.

7. The main body of the waterproof hearing aid according to claim 5, wherein a thickness of the pad body is 0.5-1. mm, and a thickness of the boss is 0.2-0.5 mm.

8. The main body of the waterproof hearing aid according to claim 1, wherein the liner is provided with a corresponding mounting protrusion; the waterproof pad and the FPC board are provided with a waterproof pad mounting hole and an FPC board mounting hole, respectively; and
the corresponding mounting protrusion passes through the waterproof pad mounting hole and the FPC board mounting hole to achieve fixation.

9. The main body of the waterproof hearing aid according to claim 1, wherein the waterproof pad is a soft rubber pad.

10. The main body of the waterproof hearing aid according to claim 2, wherein the waterproof pad is a soft rubber pad.

11. The main body of the waterproof hearing aid according to claim 3, wherein the waterproof pad is a soft rubber pad.

12. The main body of the waterproof hearing aid according to claim 4, wherein the waterproof pad is a soft rubber pad.

13. The main body of the waterproof hearing aid according to claim 5, wherein the waterproof pad is a soft rubber pad.

14. The main body of the waterproof hearing aid according to claim 6, wherein the waterproof pad is a soft rubber pad.

15. The main body of the waterproof hearing aid according to claim 7, wherein the waterproof pad is a soft rubber pad.

16. The main body of the waterproof hearing aid according to claim 8, wherein the waterproof pad is a soft rubber pad.
